(19) United States
(12) Patent Application Publication
(10) Pub. No.: US 2005/0200276 A1
(43) Pub. Date: Sep. 15, 2005

(54) Electroluminescence device and organic electroluminescence display

(76) Inventors: Albrecht Uhlig, Berlin (DE); Kerstin Nolte, Berlin (DE); Thomas Schrader, Berlin (DE)

Correspondence Address: MCGUIREWOODS, LLP, 1750 TYSONS BLVD, SUITE 1800, MCLEAN, VA, 22102, US

(21) Appl. No.: 11/019,452

(22) Filed: Dec. 23, 2004

(30) Foreign Application Priority Data
Mar. 11, 2004 (EP) 04 090 103.5
Jul. 12, 2004 (KR) 04-53870

(51) Int. Cl. H01J 1/62

(52) U.S. Cl. 313/506

(57) ABSTRACT

An organic electroluminescence device and display having high efficiency and improved durability. A layer formed of polysiloxane, fluorinated hydrocarbon, and/or derivatives thereof is interposed between an anode and a hole injection layer/hole transport layer, thus improving the durability of the organic electroluminescence device.

### CROSS REFERENCE TO RELATED APPLICATION

This application claims priority to and the benefit of European Patent Application No. 04090103.5, filed on Mar. 11, 2004, and Korean Patent Application No. 10-2004-0053870, filed on Jul. 12, 2004, which are hereby incorporated by reference for all purposes as if fully set forth herein.

### BACKGROUND OF THE INVENTION

1. Field of the Invention

The present invention relates to an electroluminescence (EL) device and a display having the same, and more particularly, to an EL device and an organic EL display with improved durability.

2. Discussion of the Background

Generally, electroluminescence is the basic principle of an organic light-emitting device. Electrons and holes are injected into a semiconductor material where they recombine, become electrically neutral, and excite molecules that return to a ground state and emit light. Organic light-emitting devices (LEDs) may be divided into small molecular organic LEDs (SM-OLEDs) and polymer organic LEDs (pLEDs).

An efficiently operating organic EL device has high electron and hole conductivity, as well as high light emitting efficiency which may be defined by the amount of emitted light per injected charge carrier. An organic EL device may be formed with multiple layers to improve its efficiency.

Heitecker et al., Applied Physics Letters vol. 82 No. 23 (2003 Jun. 09) pp. 4178, discloses the use of poly(ethylene dioxy-thiophene)-polystyrene sulfonic acid (PDOT:PSS) as a hole transport material or a hole transport layer (HTL) in an SM-OLED and a pLED. The HTL smoothe anodes and facilitates hole injection. The anodes may be formed of indium-tin-oxide (ITO), and the HTL may be deposited on them by spin coating, inkjet printing, or other methods. The HTL may improve the organic EL device's efficiency, which reduces the organic EL device's and/or an organic EL display device's power dissipation.

However, using an HTL in an organic EL device may decrease the device's durability. For example, Lin Ke et. al., Mat. Res. Symp. Proc vol. 710 (2002) pp. 239, discloses that indium, as a contaminant of pLEDs, increases a non-radial recombination of electron-hole couples compared to a radial recombination of the electron-hole couples. The ITO from the anodes may be the source of the contaminant. In this case, the HTL, which is acidic, induces a chemical reaction with the anode that causes the radiation, diffusion, and/or movement of indium to a light-emitting layer material.

Chua et al., Applied Physics Letters vol. 81 No. 6 (2002 Aug. 05) pp. 1119-1121, discloses an organic EL device with an ITO/parylene/PDOT:PSS/Ph-PPV/parylene/CA/Al structure. The parylene layer may be interposed between the anode, (i.e. ITO) and the HTL (i.e. PDOT:PSS). The parylene layer smoothes the light-emitting layer (i.e. Ph-PPV) and operates as an anode. The generation of hot spots, which denote areas having increased current conductivity, should be reduced.

U.S. Pat. Nos. 4,954,528, 5,643,658, and 5,476,725 disclose a silicon carbide layer, a silicon oxide layer, and a tantalum oxide layer, respectively, between an HTL and an anode in an organic EL device.

U.S. Patent Application Publication No. 2003/0025445 A1, assigned to Samsung SDI, which is also the assignee of this present invention, discloses the use of a metal organic compound with the formula R₁R₂MR₃R₄, wherein “M” is one metal selected from the group consisting of Ti, Pt and metals belonging to groups 3B and 4B of periods 3 to 5 and R₁₋₄ denotes a silicon organic compound. The metal organic compound may be interposed between an ITO anode and an HTL or between a light-emitting layer and the HTL. However, such an intermediate layer may not provide a desired sealing integrity for preventing an acidic attack by the HTL and for mechanical stability, and thus it may not satisfactorily improve an organic EL device's durability.

International patent application publication WO 02/093662 A2 discloses an organosilane thin layer as a dielectric intermediate layer on an ITO layer for an OLED. To produce the organosilane thin layer, the surface of the ITO layer is exposed to a liquid or vapor organosilane adhesion promoter and oxidized by oxygen plasma or a gas discharge including an oxygen radical. Accordingly, a dielectric thin layer may be generated that improves the injection of charges from the ITO layer to the OLED and improves the device's efficiency. However, the acidic attack of an HTL on the ITO layer may not be prevented.

Each of the above-described organic EL devices, which include an HTL to improve hole conductivity, may have a short lifetime.

### SUMMARY OF THE INVENTION

The present invention provides an organic EL device with an HTL or HIL, and a display device having the same, with improved durability.

Additional features, of the invention will be set forth in the description which follows, and in part will be apparent from the description, or may be learned by practice of the invention.

The present invention discloses an organic electroluminescence device comprising a substrate, an anode arranged on the substrate, an anode protection layer arranged on the anode, a hole auxiliary layer, arranged on the anode protection layer, an organic light-emitting layer arranged on the hole auxiliary layer, and a cathode arranged on the organic light-emitting layer. The a hole auxiliary layer comprises a hole injection layer or a hole transport layer, and the anode protection layer includes one or more compounds selected from the group consisting of a fluorinated polysiloxane, a fluorinated hydrocarbon, and any of their derivatives.

The present invention also discloses an organic electroluminescence display including the organic electroluminescence device described above.

The present invention also discloses an organic electroluminescence display comprising a substrate, a display region formed on the substrate, and a sealing member for sealing the display region. More than one pixel is formed in the display region, and each pixel includes an anode, an anode protection layer arranged on the anode, a hole auxiliary layer, which comprises a hole injection layer or an HTL, arranged on the anode protection layer, an organic light-emitting layer arranged on the hole auxiliary layer, and a cathode arranged on the organic light-emitting layer. The anode protection layer includes one or more compounds selected from the group consisting of a fluorinated polysiloxane, a fluorinated hydrocarbon, and any of their derivatives.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a sectional view of an organic EL device according to an exemplary embodiment of the present invention.

FIG. 2 is a diagram showing a reaction for forming an anode protection layer formed of polysiloxane;

FIG. 3 is a diagram showing an anode protection layer formed by multiple polysiloxane layers.

FIG. 4A is a perspective view of an organic EL display according to an exemplary embodiment of the present invention.

FIG. 4B is a sectional view cut along the line I-I of FIG. 4A.

FIG. 4C is an enlarged view showing a portion of the organic EL display denoted by A of FIG. 4B.

FIG. 4D is an enlarged view showing a portion of the organic EL display denoted by B of FIG. 4C.

### DETAILED DESCRIPTION OF THE ILLUSTRATED EMBODIMENTS

The present invention will now be described more fully with reference to the accompanying drawings, which show exemplary embodiments of the present invention.

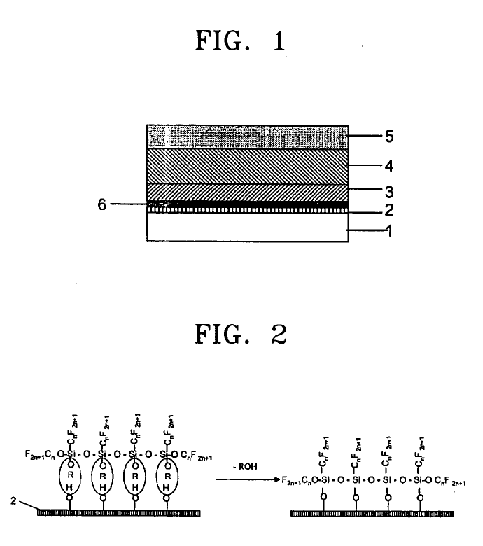

FIG. 1 is a sectional view of an organic EL device according to an exemplary embodiment of the present invention. Referring to FIG. 1, an anode 2 is arranged on a surface of a substrate 1, which may be glass. An anode protection layer 6 formed of fluorinated hydrocarbon and/or fluorinated polysiloxane, or a derivative thereof, may be arranged on the anode 2. A hole auxiliary layer 3, which comprises a hole transport layer (HTL) or a hole injecting layer (HIL), for improving hole injection and/or hole transport, may be arranged on the anode protection layer 6. If the hole auxiliary layer comprises both layers, the HIL may be interposed between the HTL and the anode protection layer 6. A light-emitting polymer layer 4 may be arranged on a surface of the HTL 3, and a cathode 5, which may comprise more than one layer, may be arranged on a surface of the light-emitting polymer layer 4.

A manufacturing process of the organic EL device shown in FIG. 1 will now be described in detail.

A 180 nm thick ITO anode 2 may be coated on the substrate 1, which may be formed of boro silicate glass. In order for the organic EL device to have a light-emitting surface area of 2 mm², the anode 2 may be formed by arranging a 2 mm wide ITO strip on the center of the substrate 1. The substrate 1 may be cleaned in an isopropanol supersonic wave bath for five minutes and dried under a nitrogen flow. The substrate 1 may also be UV/ozone processed for about 10 minutes.

A polysiloxane layer (i.e. the anode protection layer 6) is then formed. To this end, 10 percent by weight of heptadecafluoro-1,1,2,2-tetrahydrodecyl-dimethy-chloro silane is formed by agitating 96% ethanol for five minutes. The substrate 1 having the anode 2 may be soaked in the above-described solution and agitated for five minutes. Then, the substrate 1 is air-dried, and the substrate 1 having the anode 2 and the anode protection layer 6 formed thereon, is dried on a heating plate at a temperature of 160° C. for 30 minutes.

The anode protection layer 6 may also be formed of a polytetrafluorethylene layer. In this case, the substrate 1 having the anode 2 may be placed in a microwave plasma plant. Then, C₃F₈ gas having a flow rate of 200 ml/min may be injected into a chamber with a pressure of 200 Pa, and a plasma power of 200 W may be applied to generate polytetrafluorethylene. Polytetrafluorethylene may then be deposited on a 2 mm² region in the center of the substrate by using a shadow mask.

Accordingly, a 2 nm thick anode protection layer 6 may be formed by depositing polytetrafluorethylene. Other fluorinated gases, such as C₃F₆ or C₂F₄, may be used instead of C₃F₈ gas. The anode protection layer 6 may be in a range of 0.1 nm to 50 nm thick.

Next, a 50 nm thick HTL layer, as the hole auxiliary layer 3, may be formed by spin coating LVW 142, which is Baytron P® manufactured by Bayer AG, and drying it at a temperature of 200° C. under a nitrogen atmosphere for 10 minutes. The HTL may be in a range of 30 nm to 150 nm thick.

Next, a 70 nm thick light-emitting polymer layer 4, comprising SCB 11, which is DOW LUMINATION® manufactured by Dow Chemical, may be deposited by spin coating under a nitrogen atmosphere, by using 1 part by weight of anhydrous xylol, and then dried on a heating plate at a temperature of 110° C. for 10 minutes. The light-emitting polymer layer 4 may be in a range of 50 nm to 120 nm thick.

The substrate may then be transferred to a vacuum plant under a nitrogen atmosphere. A 2 mm² cathode 5, overlapping the anode 2 at the center of the substrate, may be vapor deposited by thermally depositing 1 nm thick lithium fluoride, 10 nm thick calcium, and 500 nm thick aluminium layers. A surface may be formed on the cathode 5 for coupling to an external power supply.

The substrate may then be sealed in glass panels using an epoxy adhesive in order to prevent oxygen and moisture from penetrating the organic EL device. The device's operation may be tested by applying a voltage of 3 to 4V between the anode 2 and the cathode 5.

The anode protection layer 6 may reduce the acidic attack by the HTL 3 on the anode 2. Additionally, the polysiloxane or fluorinated hydrocarbon anode protection layer 6 may operate as a diffusion barrier against protons. Furthermore, the anode protection layer 6 may operate as a diffusion barrier against metal cations, such as indium, and prevent diffusion and/or migration of the metal cations to the light-emitting polymer layer 4, thereby reducing damage to the light-emitting polymer layer 4 caused by metal cations and increasing the device's durability.

FIG. 2 shows a reaction of the condensation of polysiloxane and the anode protection layer 6 formed from the polysiloxane. Referring to FIG. 2, polysiloxane and fluorinated alkyl side chains may be used to induce a water-repellent function by using a thin layer and to form the anode protection layer 6 without affecting the electric or optical characteristic of the organic EL device. After the reaction between the anode 2 and polysiloxane, the siloxanes may form a diffusion barrier against protons, as well as the metal cations, through covalent bonds.

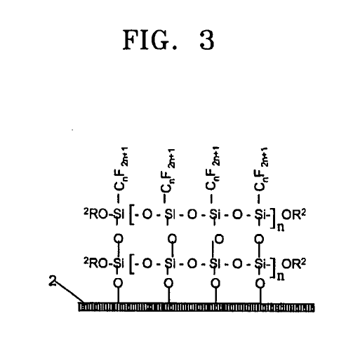

FIG. 3 shows an anode protection layer 6, which may be formed of multiple polysiloxane layers to better perform as the diffusion barrier against the protons and the metal cations.

While a passive matrix (PM) organic EL device is described above, the present invention is not limited thereto.

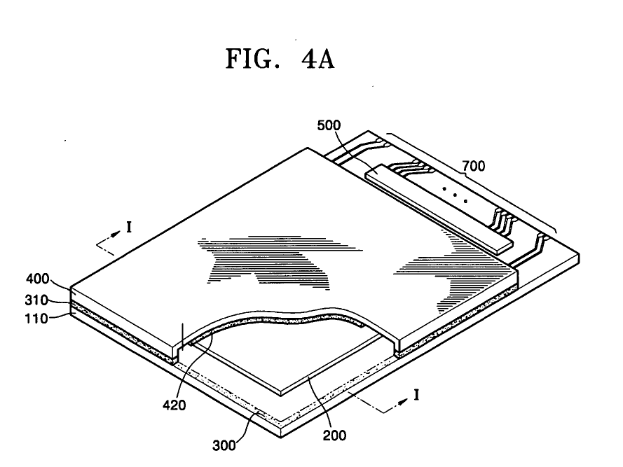

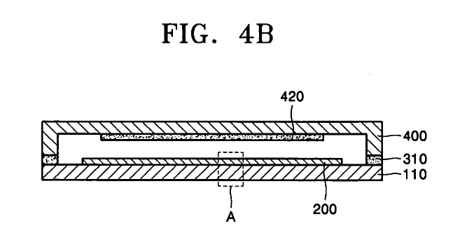

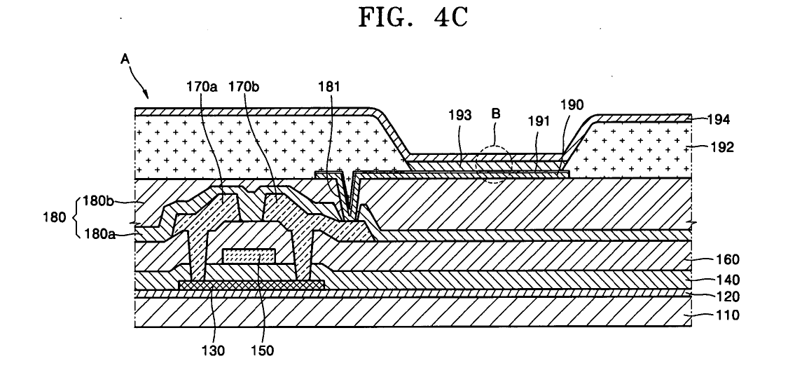

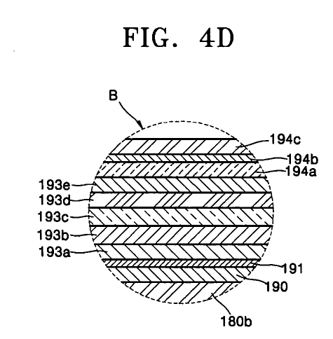

FIG. 4A, FIG. 4B, FIG. 4C and FIG. 4D show an active matrix (AM) organic EL display according to an exemplary embodiment of the present invention. FIG. 4A and FIG. 4B are a perspective view of the EL display and a sectional view cut along the line I-I of FIG. 4A, respectively. A display region 200 may be formed on a substrate 110. A parallel driving circuit unit 500, which applies electric signals to the display region 200, and a terminal unit 700, which inputs and outputs the electric signals to and from the display region 200, may be formed on at least one side of the substrate 110.

The display region 200 may be sealed by a sealing member. In the present exemplary embodiment, a sealing substrate 400 is used as shown in FIG. 4A; however, the sealing member may be formed of a sealing layer or another sealing material. The substrate 110 and the sealing substrate 400 seal the display region 200 within a sealing region 300, which is formed around the display region 200. As shown in FIG. 4B, a moisture absorbent material 420, for removing moisture entering the sealing region 300, may be arranged on at least one portion of the sealing region 300. In the present exemplary embodiment, the moisture absorbent material 420 is tape and may be attached to one surface of the sealing substrate 400. The shape and the location of the moisture absorbent material 420 may vary.

FIG. 4C is a sectional view showing a pixel of the display region 200, which is denoted by reference character A in FIG. 4B. Referring to FIG. 4C, a semiconductor active layer 130 is formed on a buffer layer 120, which is formed on a surface of the substrate 110. The semiconductor active layer 130 may be an amorphous or polycrystalline silicon layer. The semiconductor active layer 130 includes channel, source, and drain regions, and the source and drain regions may be doped with N+ type or P+ type dopant. The semiconductor active layer 130 may be formed of an organic semiconductor.

A gate electrode 150 is formed on a gate insulating layer 140 at a position corresponding the channel region of the semiconductor active layer 130. The gate electrode 150 may be formed of MoW and Al/Cu.

The gate insulating layer 140 insulates the gate electrode 150 from the semiconductor active layer 130. An insulating interlayer 160, which may comprise a single layer or multiple layers, is formed on the gate electrode 150 and the gate insulating layer 140, and source/drain electrodes 170a and 170b are formed thereon. The source/drain electrodes 170a and 170b may comprise Mo or Al. In other words, the source/drain electrodes 170a and 170b may be formed of MoW or Mo/Al. Additionally, the source/drain electrodes 170a and 170b may be thermally processed in order to form a sufficient ohmic contact for the semiconductor active layer 130.

The insulating layer 180 includes at least two layers, such as a planarization layer 180b, for planarizing a passivation layer 180a, and/or a lower thin film transistor layer. The passivation layer 180a may be formed of an inorganic material, such as SiNₓ and SiO₂, and the planarization layer 180b may be formed of an organic material, such as benzocyclobutene (BCB) or acryl. A via hole 181 is formed in the insulating layer 180 to expose either the source electrode 170a or the drain electrode 170b. In FIG. 4C, the via hole 181 exposes the drain electrode 170b.

An anode 190 may be formed on a surface of the insulating layer 180 as a pixel electrode. The anode 190 may include a conductive oxide, such as ITO. An anode protection layer 191 may be formed on a portion of the anode 190 that contacts a subsequently formed organic EL unit. The composition and method of forming the anode protection layer 191 is the same as those for the anode protection layer 6 shown in FIG. 1.

After forming the anode protection layer 191, a pixel defining layer 192, which defines a pixel, may be formed, and an organic EL unit 193, including a light-emitting layer 193c, may be arranged on a surface of the anode protection layer 191 exposed by an opening in the pixel defining layer 192. FIG. 4D is an enlarged sectional view showing an area B in FIG. 4C. Referring to FIG. 4D, the organic EL unit 193 may include an HIL 193a, an HTL 193b, the light-emitting layer 193c, an electron transport layer 193d, and an electron injection layer 193e. The construction of the organic EL unit 193 shown in FIG. 4D may vary. For example, as is the case in FIG. 1, an HIL, an HTL, or an HIL and HTL may be included in the organic EL unit 193.

A cathode 194 may be formed on the organic EL unit 193, and it may include more than one layer. Referring to FIG. 4D, the cathode 194 includes a LiF layer 194a as an alkali fluoride layer, a Ca layer 194b, and an Al layer 194c; however, the composition of the cathode 194 may vary.

The AM organic EL display according to the exemplary embodiment described herein is a rear display. The present invention, however, may also be applied to a front display, including a reflective anode formed of Al/ITO and a cathode formed of Mg:Ag and a transparent conductive oxide. Additionally, the present invention may also be applied to a display that is both a front and rear emitting display.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. An organic electroluminescence (EL) device, comprising:
a substrate;
an anode arranged on the substrate;
an anode protection layer arranged on the anode;
a hole auxiliary layer arranged on the anode protection layer;
an organic light-emitting layer arranged on the hole auxiliary layer; and
a cathode arranged on the organic light-emitting layer,
wherein the hole auxiliary layer comprises a hole injection layer or a hole transport layer (HTL),
wherein the anode protection layer includes one or more compounds selected from the group consisting of a fluorinated polysiloxane, a fluorinated hydrocarbon, and any derivatives thereof.

2. The organic EL device of claim 1, wherein the anode protection layer includes fluorinated polysiloxane bonded by a covalent bond.

3. The organic EL device of claim 1, wherein the anode protection layer includes fluorinated hydrocarbon, which includes polytetrafluoroethylene.

4. The organic EL device of claim 1, wherein the anode protection layer includes fluorinated polysiloxane, which is manufactured by heptadecafluoro-1,1,2,2-tetrahydrodecyl-dimethyl-chloro silane.

5. The organic EL device of claim 1, wherein the anode protection layer comprises multiple layers including fluorinated polysiloxane.

6. The organic EL device of claim 1, wherein the anode protection layer is in a range of 0.1 nm to 50 nm thick.

7. The organic EL device of claim 1, wherein the HTL is formed of polyaniline (PANI) or poly(ethylene dioxy-thiophene)-polystyrene sulfonic acid (PDOT:PSS).

8. The organic EL device of claim 7, wherein the HTL is in a range of 30 nm to 150 nm thick.

9. The organic EL device of claim 1, wherein the anode comprises indium-tin-oxide (ITO).

10. The organic EL device of claim 1, wherein the organic light-emitting layer comprises more than one of poly(phenylenvinylenes) and polyfluorenes.

11. The organic EL device of claim 10, wherein the organic light-emitting layer is in a range of 50 nm to 120 nm thick.

12. The organic EL device of claim 1, wherein the cathode comprises:
a first cathode layer formed of calcium; and
a second cathode layer formed of aluminum and arranged on the first cathode layer.

13. The organic EL device of claim 12, wherein the first cathode layer is 10 nm thick and the second cathode layer is 500 nm thick.

14. The organic EL device of claim 1,
further comprising a layer interposed between the organic light-emitting layer and the cathode,
wherein the layer includes more than one of alkali fluoride and alkali earth fluoride.

15. The organic EL device of claim 14, wherein the layer forms part of the cathode.

16. The organic EL device of claim 15, wherein the alkali fluoride is lithium fluoride.

17. The organic EL device of claim 1, further comprising a sealing member.

18. An organic electroluminescence device, comprising:
an anode;
an anode protection layer arranged on the anode;
a hole transport layer arranged on the anode protection layer;
an organic light-emitting layer arranged on the hole transport layer; and
a cathode arranged on the organic light-emitting layer,
wherein the anode protection layer includes one or more compounds selected from the group consisting of a fluorinated polysiloxane, a fluorinated hydrocarbon, and any derivatives thereof.

19. An organic electroluminescence (EL) display, comprising:
a substrate;
a display region formed on the substrate; and
a sealing member for sealing the display region,
wherein more than one pixel is formed in the display region, and
wherein each pixel comprises:
an anode;
an anode protection layer arranged on the anode;
a hole auxiliary layer, comprising a hole injection layer or a hole transport layer, arranged on the anode protection layer;
an organic light-emitting layer arranged on the hole auxiliary layer; and
a cathode arranged on the organic light-emitting layer,
wherein the anode protection layer includes one or more compounds selected from the group consisting of a fluorinated polysiloxane, a fluorinated hydrocarbon, and any derivatives thereof.

20. The organic EL display of claim 19, wherein the anode protection layer includes fluorinated polysiloxane bonded by a covalent bond.

21. The organic EL display of claim 19, wherein the anode protection layer includes fluorinated hydrocarbon, which includes polytetrafluoroethylene.

22. The organic EL display of claim 19, wherein the anode protection layer includes fluorinated polysiloxane, which is manufactured by heptadecafluoro-1,1,2,2-tetrahydrodecyl-dimethyl-chloro silane.

23. The organic EL display of claim 19, wherein the anode protection layer includes multiple layers including fluorinated polysiloxane.
